(19) United States
(12) Patent Application Publication
(10) Pub. No.: US 2011/0253217 A1
(43) Pub. Date: Oct. 20, 2011

(54) Controlled Alignment in Polymeric Solar Cells

(75) Inventors: Jeffrey C. Grossman, Berkelyline, MA (US); Alexander K. Zettl, Kensington, CA (US)

(73) Assignee: THE REGENTS OF THE UNIVERSITY OF CALIFORNIA

(21) Appl. No.: 13/121,932

(22) PCT Filed: Sep. 28, 2009
(86) PCT No.: PCT/US09/58549

§ 371 Date: Jul. 1, 2011

(30) Foreign Application Priority Data
Sep. 30, 2008 (US) 61101233

(51) Int. Cl. H01L 51/46; H01L 31/0248; H01L 31/06; B82Y 99/00

(52) U.S. Cl. 136/263; 136/252; 136/255; 438/3; 977/938; 977/946; 977/948; 438/82; 977/734; 257/E31.002

(57) ABSTRACT

Disclosed are methods of using magnetic or electric fields to align magnetically responsive nanoparticles in a polymeric matrix, which has not yet been completely solidified. The nanoparticles are preferably magnetically doped, then blended with photovoltaic polymer material to form devices. The methods provided are particularly useful for the formation of solar cell devices. The devices include nanostructured electron-conducting channels arranged approximately parallel to one another, where the channels comprise magnetically doped materials, as well as photovoltaic materials interspersed with the nanostructured electron-conducting channels. The method provides a way to control the morphology of blended photovoltaic devices, which will improve efficiencies. In addition, the new method provides a way to control the growth of novel, cheap, solar cells, which can in turn lead to enhanced performance.

### RELATED APPLICATIONS

This application is the national phase application of International application number PCT/US2009/058549, filed Sep. 28, 2009, which claims priority to and the benefit of U.S. Provisional Application No. 61/101,233, filed on Sep. 30, 2008, which is hereby incorporated by reference in its entirety.

### STATEMENT OF GOVERNMENTAL SUPPORT

This invention was made with government support under Contract No. DE-AC02-05CH11231 awarded by the U.S. Department of Energy and under National Science Foundation COINS Grant No EEC-0425914. The government has certain rights in the invention.

### FIELD OF THE INVENTION

The present invention relates to the field of materials science, and more particularly to the fabrication of polymeric solar cells.

### BACKGROUND OF THE INVENTION

Polymer based photovoltaic devices are an attractive alternative to conventional, inorganic solar cells. These lightweight elements for solar energy conversion have various important advantages over their silicon counterparts, such as easy processing, mechanical flexibility, the potential for low-cost fabrication of large areas, and ample possibilities of optoelectronic tuning of their material properties. Today's most efficient polymer-based solar cells are constructed from an interpenetrating network of an electron-donating polymer and an electron-accepting material. Intimate intermixing of the two components of such a bulk-heterojunction (BHJ) solar cell ensures efficient dissociation of strongly bound excitons that are generated upon illumination. Subsequent charge transfer from the polymer to the n-type acceptor is followed by dissociation of the bound electron-hole pair and transport of the spatially separated holes and electrons through the respective phases to the electrodes.

Solar cells based on such blends of electron- and hole-conducting materials hold enormous promise for delivering inexpensive solar energy while maintaining high efficiency and durability. However, to date the best efficiencies achieved with these solar cells is 5-6%, still far too low for many practical applications.

There are many aspects of these devices that are little understood and may provide avenues for improved efficiency. One direction for improvement, as described below, lies in the development of better techniques for controlling the structure of the blended morphology. Currently, the two parameters used in synthesizing polymer blend nanoscale solar cells are temperature and physical mixing time and method. There is essentially very little control apart from “shaking, and baking”. Yet, it has been demonstrated repeatedly that morphology plays a crucial role in device performance. Furthermore, if one could attain a more ideal morphology in these blended solar cells, namely one in which the electron conducting channels are vertically aligned and take up very little of the fractional weight percent, a factor of two in efficiency could be possible immediately. Accordingly, there is a need in the art for methods of controlling the morphology of such blends.

### Specific Patents and Publications

“Characterization of large area flexible plastic solar cells based on conjugated polymer/fullerene composites”, by Gebeyehu et al., Int. J. of Photoenergy, Vol. 1, pp. 1-5, 1999, describes various blends of polymers and fullerenes, as well as methods of protecting the composites from degradation.

“Fullerenes and nanostructured plastic solar cells”, by Knol and Hummelen, in Electric Properties of Novel Materials: XII International Winterschool, edited by H. Kuzmany et al., 1998, pp 523-526, describes the design of fullerene derivatives and π-conjugated donor molecules that can function as acceptor-donor pairs and (supra-) molecular building blocks in organized, nanostructured, interpenetrating networks, forming a bulk-heretojunction with increased charge carrier mobilities.

U.S. Pat. No. 5,986,206, titled “Solar Cell”, issued to Kambe and Dardi Nov. 16, 1999, describes polymer based solar cells that incorporate nanoscale carbon particles as electron acceptors.

U.S. Pat. No. 5,454,880, titled “Conjugated Polymer-Acceptor Heterojunctions: Diodes, Photodiodes, and Photovoltaic Cells”, issued to Sariciftci and Heeger on Oct. 3, 1995, describes methods of fabricating heterojunction diodes from semiconducting (conjugating) polymers and acceptors such as, for example fullerenes, Buckminsterfullerines, and C₆₀ and use of such diodes as photovoltaic cells.

### SUMMARY OF THE INVENTION

The following brief summary is not intended to include all features and aspects of the present invention, nor does it imply that the invention must include all features and aspects discussed in this summary.

The present invention provides methods of using magnetic or electric fields to align semiconductor nanoparticles as they are blended with photovoltaic materials to form devices, as well as devices made from such methods. In order to do this, nanoparticles are magnetically doped, i.e., attached to one or more atoms of a magnetic material The dopant may be ferromagnetic or paramagnetic. The nanoparticles are added in sufficient quantity to form a conductive channel to an electrode. The quantity of nanoparticles may be advantageously reduced in the present device, because the particles can be properly arranged and need not occupy space otherwise available to photovoltaic polymer. This is advantageous when using particles such as fullerenes, which do not absorb light. Thus one may use a ratio of about 1:1 nanoparticles to polymer, or less, such as 1:2. The alignment of the nanoparticles essentially also results in an alignment of the polymer between the particles.

Thus, in one embodiment, the present invention provides a method of making an optoelectronic device, comprising providing electron-conducting nanoparticles, doping the nanoparticles with a magnetic material to make doped nanoparticles, and blending the doped nanoparticles with a photovoltaic material which exists in a fluid or semisolid state, while applying a magnetic or electric field in order to cause a rearrangement of the nanoparticles. In one aspect of this embodiment, doping comprises inserting a magnetic material into the nanoparticle, i.e., endohedral dopant. Alternatively, the magnetic material may be attached to the surface of the nanoparticle, e.g., by a chemical linkage.

In another aspect, the present invention comprises a polymeric solar cell design in which the heterojunction is between two different polymers, that is, a donor polymer and an acceptor polymer. In this case, both active materials can exhibit a high optical absorption coefficient. For example, a photovoltaic combination can be prepared from MDMO-PPV (poly(2-(3,7-dimethyloctyloxy)-5-methoxy-1,4-phenylenevinylene) as a donor and PCNEPV (poly(cyanoether phenylenevinylene)) as an acceptor. In this case, one of the polymers is linked to a magnetic particle.

In another aspect of the invention, a particular magnetic field or electric field is used to direct an alignment of the magnetically functionalized semiconductor nanoparticles, so as to direct them into an improved configuration for accepting a member of an exciton pair in a polymeric photovoltaic cell. The cell is formed as a thin film on a substrate, and an electromagnetic field emitting apparatus is positioned adjacent to the substrate while the polymer is in a fluid state, so as to cause the magnetically functionalized nanoparticles within the polymer to move into a desired configuration.

In another embodiment, the present invention provides a photovoltaic cell, comprising nanostructured electron-conducting channels, made of magnetically doped materials that are arranged in a series of columns, forming conductive channels, which are approximately parallel to one another, and a photovoltaic material interspersed between the nanostructured electrically-conducting channels. Preferably, the nanostructured electron-conducting channels have a channel-to-channel spacing no larger than an electron-hole recombination length in the photovoltaic material. This may be on the order of 1-20, 10-20, or 5-15 nm. Also preferably, the device structure is a solar cell device. It should be noted that the doped nanoparticles may be combined, e.g., by sintering, prior to application of the electromagnetic field.

In one aspect of the invention, the nanostructured electron-conducting channels comprise carbon. Preferably, the nanostructured conducting channels comprise spherical fullerene molecules, such as C₆₀, functionalized C₆₀, such as C₆₀-PCBM (PCBM is [6,6]-phenyl-C₆₁-butyric acid methyl ester.), as well as other graphitic molecules such as single wall carbon nanotubes, multi wall carbon nanotubes, as well as non carbon nanotubes, various nanowires, and nanocrystals which may be spherical, elliptical or tetrapodal, and may be so-called “quantum dots,” i.e., nanocrystals, composed of periodic groups of II-VI, III-V, or IV-VI materials, ranging from 2-10 nanometers (10-50 atoms) in diameter. The nanostructured conducting channels may contain a single species of particle, or multiple species of particles, and any magnetic functionality, including but not limited to manganese, chromium, iron, cobalt, and nickel.

In a further aspect of the invention, the photovoltaic cell is designed for optimum match between semiconductor species, based on band gap, quantum efficiency, etc. That is, the polymer is matched to the nanoparticle material in one or more layers. The polymer material may be selected from a variety of is a polymer, such as P3HT (crosslinked poly(3-hexylthiophene), PEDOT (Poly(3,4-ethylenedioxythiophene), PEDOT(PSS): Poly(3,4-ethylenedioxythiophene) poly(styrenesulfonate), MDMO-PPV(poly(2-methoxy-5-(3′,7′-dimethyl-octyloxy))-p-phenylene vinylene) , or PFTBT (poly fluorine benzothiadiazole copolymer).

### BRIEF DESCRIPTION OF THE DRAWINGS

The foregoing aspects and others will be readily appreciated by the skilled artisan from the following description of illustrative embodiments when read in conjunction with the accompanying drawings.

FIG. 1A shows an example of the present inventive structure.

FIG. 1B is prior art.

FIG. 1C shows C₆₀-PCBM, a possible material used at 104.

FIG. 2 is schematic diagram showing the behavior of unfunctionalized C₆₀ versus magnetically functionalized C₆₀ in the presence of an electric of magnetic field.

FIG. 3 is a schematic diagram of magnetic field lines, taken from Practical Physics, Macmillan and Company (1914), on which are superimposed possible nanoparticle alignments according to the present invention. Iron filings trace the path of the magnetic field lines generated by a bar magnet.

FIG. 4 is a schematic drawing of a photovoltaic active layer prepared through the use of electromagnets. The view is along the edge of the thin film, where the light will enter from the top.

### DETAILED DESCRIPTION OF THE INVENTION

### Definitions

Unless defined otherwise, all technical and scientific terms used herein have the same meaning as commonly understood by those of ordinary skill in the art to which this invention belongs. Although any methods and materials similar or equivalent to those described herein can be used in the practice or testing of the present invention, the preferred methods and materials are described. Generally, nomenclatures utilized in connection with, and techniques of, material science, physics and chemistry are those well known and commonly used in the art. Certain experimental techniques, not specifically defined, are generally performed according to conventional methods well known in the art and as described in various general and more specific references that are cited and discussed throughout the present specification.

The term “photovoltaic device” is used in its conventional sense to mean a solid-state electrical device that converts light directly into direct current electricity of voltage-current characteristics that are a function of the characteristics of the light source and the design of the device. By way of example, solar photovoltaic devices are made of various semiconductor materials including silicon, cadmium sulfide, cadmium telluride, and gallium arsenide, and in single crystalline, multicrystalline, or amorphous forms, as well as the presently discussed bendable materials.

The term “nanoparticle material” means a solid semiconductor material in nanoparticle form useful in a photovoltaic cell, and, further, which can be placed in a liquid without loss of particulate properties or loss of activity, The nanoparticles are of a nanoscale size, e.g., from 1 nm to about 500 nm in at least one dimension (e.g., diameter), e.g., less than about 200 nm, less than about 100 nm, less than about 50 nm, or even less than about 20 nm.

Essentially spherical particles are preferred, but, for purposes of electromagnetic alignment according to the present method, nanowires, nanorods and the like may also be used. The term “nanocrystal” means a nanoparticle that is substantially monocrystalline.

The term “polymer material” is used in its conventional sense, and is particularly intended to mean a material which can be prepared in a liquid or semi-solid or paste like form (as either a polymer, monomer or pre-polymer) and cast or molded into a particular structure, preferably a thin film, e.g., 100-300 nm thick. The polymer material is cured or further polymerized into a solid. The polymer material herein is useful as a hole or electron conductor in a polymer-based photovoltaic device. A preferred polymer material has conjugated double bonds when polymerized (a “conjugated polymer”) and may act as either a semiconductor an electron donor, or an electron acceptor.

The term “magnetic functionality” means that a material having “magnetic functionality” is magnetically responsive. This property in certain embodiments may be intrinsic. In other embodiments, a non-magnetic material (carbon) is functionalized by addition of a magnetic particle (or single atom), which particle may be covalently or noncovalently chemically bonded to the material, or contained within the material physically (endohedral). The magnetic functionality as defined here imparts magnetic properties to the material so functionalized, e.g. a nanoparticle material, making it able to move in response to a magnetic or electric field. The magnetic particle (or atom) may be paramagnetic, a material which has a small and positive susceptibility to magnetic fields. These materials are slightly attracted by a magnetic field and the material does not retain the magnetic properties when the external field is removed. Paramagnetic properties are due to the presence of some unpaired electrons, and from the realignment of the electron orbits caused by the external magnetic field. Paramagnetic materials are materials which provide a relative permeability of greater than one and up to about 10. Paramagnetic materials include materials such as aluminum, platinum, manganese, chromium, magnesium, molybdenum, lithium, tantalum, and compounds thereof.

The magnetic particle may be preferably ferromagnetic. Ferromagnetic materials have a large and positive susceptibility to an external magnetic field. Ferromagnetic materials are materials which provide a relative permeability greater than 10. Ferromagnetic materials include a variety of ferrites, iron, steel, nickel, cobalt, and commercial alloys, such as alnico and peralloy. Ferrites, for example, are made of ceramic material and have relative permeabilities that range from about 50 to 200. They exhibit a strong attraction to magnetic fields and are able to retain their magnetic properties after the external field has been removed. Ferromagnetic materials have some unpaired electrons so their atoms have a net magnetic moment. They get their strong magnetic properties due to the presence of magnetic domains. In these domains, large numbers of atoms' moments (10¹² to 10¹⁵) are aligned parallel so that the magnetic force within the domain is strong.

Other magnetic functionalities may be prepared. For example, U.S. Pat. No. 4,450,086 to Homan, et al., issued May 22, 1984, entitled “Production of cadmium sulfide compositions having unusual magnetic and electrical properties,” discloses cadmium sulfide compositions, which are in a metastable state possessing greatly increased electrical conductivity and magnetic properties,

The term “electromagnetic field” means at least one of an electric field and a magnetic field. The electric field is related to the potential difference, whose unit of measure is the volt. It is generated in the presence of electric charges, and is measured in volts per meter (V/m). The higher the supply voltage of an apparatus is, the more intense the electric field that results from it becomes. The magnetic field is produced by electric currents, which can be macroscopic currents in wires, or microscopic currents associated with electrons in atomic orbits. The magnetic field, on the other hand, is defined in terms of force on moving charge in the Lorentz force law. The interaction of magnetic field with charge leads to many practical applications. Magnetic field sources are essentially dipolar in nature, having a north and south magnetic pole. The SI unit for magnetic field is the Tesla. For example, iron filings align themselves in strong magnetic fields. This reveals the shape of the field patterns. A similar thing happens with the electric fields created by high voltage and by “static electricity.”

### Overview

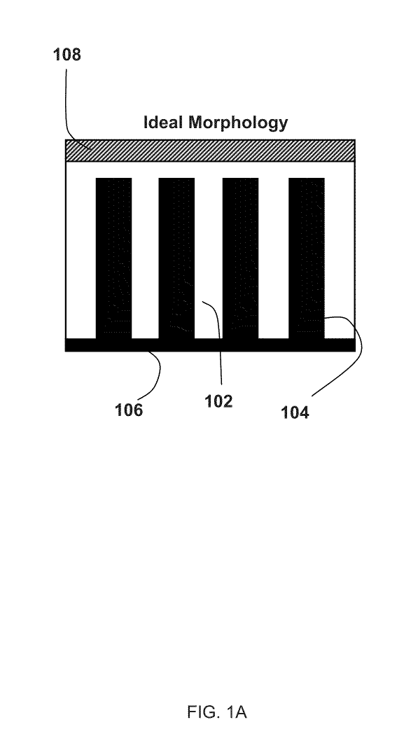

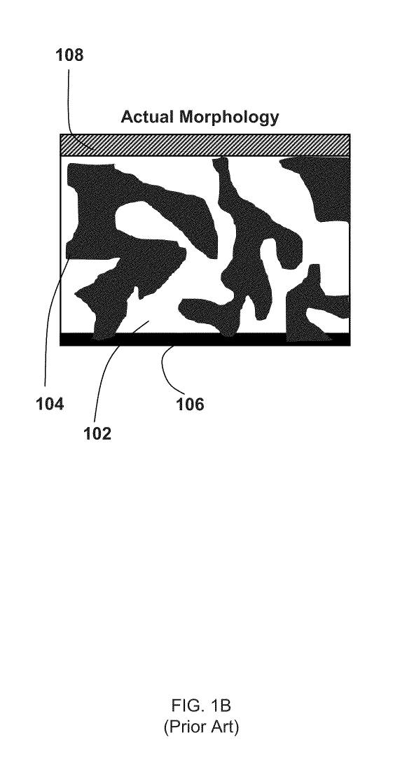

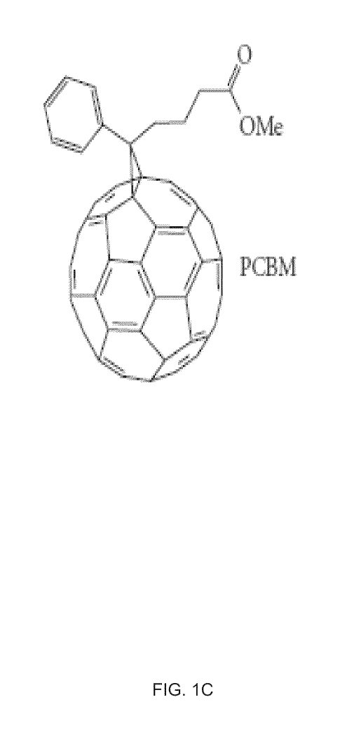

The present invention provides an optoelectronic device comprising nanostructured electron- or hole- conducting channels, made of a magnetically doped material, interspersed with a photovoltaic material, thus forming a well-ordered, bulk heterojunction. By doping the electron-conducting material with magnetic materials, for example manganese, the orientation and growth alignment of that material can be controlled by applying an external magnetic or electric field, as shown in FIG. 1. FIG. 1A and FIG. 1B are cross section schematic diagrams showing an ideal morphology versus an actual morphology of solar cells made according to various methods. The area 102 indicates photovoltaic polymer and the black area 104 indicates nanoscale electron-conducting blocks.

FIG. 1B shows a schematic representation of a (prior art polymeric photovoltaic cell composed of different semiconductors to form a bulk heterojunction in which excitons (coupled electron-hole pairs) are split at an interface between two semiconductors with offset energy levels. In traditional semiconductor theory, materials for forming photovoltaic heterojunctions have been denoted as generally being of either n, or donor type, or p, or acceptor type. Here n-type denotes that the majority carrier type is the electron. In this case, a conjugated p-type polymer conductor such as P3HT or PEDOT 102 serves as a photoactive polymer, which, when excited generated an exciton pair. The electron is transferred to a second material 104, preferably an n-type acceptor, which is a composite of molecules such as C60 or functionalized C60, such as PCBM, as a result of that material's higher electron affinity.

Thus the two materials used are characterized as electron donors and acceptors (See Table 1 below). The charge transfer occurs between two semiconductors with offset energy levels. The efficiency of such a cell is limited because excitons can generally diffuse only approximately 10-20 nm to an interface before they are extinguished. At the same time, a film thickness of approximately 100 nm is required in layer 102 to absorb the incoming light.

Currently, the highest efficiencies for such hybrid devices have been obtained with CdSe nanoparticles and polythiophenes. Similarly, solar cells based on a conjugated polymer and crystalline zinc oxide nanoparticles (ZnO) have also been prepared. The ZnO nanoparticles can act as the electron accepting species. After photoexcitation of the polymer, electrons are transferred to the ZnO. The ZnO nanoparticles can be blended with MDMO-PPV and sandwiched between electrodes as shown in FIG. 1B, where a random mixture of nanoparticles and polymer is shown. (Note that, for use in the present methods, paramagnetic semiconducting nanocrystals of ZnS or ZnO, may be doped with various concentrations of a metal ion such as magnetic Mn (See Journal of Nanoscience and Nanotechnology, Volume 5, Number 9, September 2005, p. 1503-1508(6)).

FIG. 1A shows an arrangement, according to an embodiment of the present invention, in which the donor and acceptor materials are organized in regular, repeating patterns, which can be fabricated according to the present methods, and can be optimized for incoming light absorption depths and exciton diffusion distances.

In the present invention, as in prior art solar cells, an electrode 106 is used to conduct current from the electron accepting material 104. Similarly, a transparent electrode 108 is used at the other side of the thin film, and various other substrates and connections are employed (not shown).

The present method provides a powerful new mechanism for tuning the synthesis process of the polymer-based cell by providing a way to guide the growth of the electron-conducting channels 104, e.g., as shown in FIG. 1A. It should be noted that different magnetic field patterns can be used aside from the illustrated columnar pattern. For example, concentric circles could also be formed, This ability to pattern the nanoparticle conductive channels, in turn, allows for a much more controlled solar cell design, with narrow, patterned channels leading to less electron/hole recombination, greater mobility, improved interfacial electronic structure, and more efficient photon absorption. Furthermore, the dopant atoms or molecules, while allowing for the nanostructures to be magnetized, would at the same time not have any effect on the electronic properties of the material, since the magnetically “active” spins would lie well below the Fermi energy. The materials used for electron accepting materials are described further below. For purposes of illustration, FIG. 1C shows the structure of PCBM, where it can be seen that a chemically reactive group exists for coupling to magnetic materials. As is known, PCBM, phenyl C₆₀ butyric methyl ester is a soluble form of fullerene.

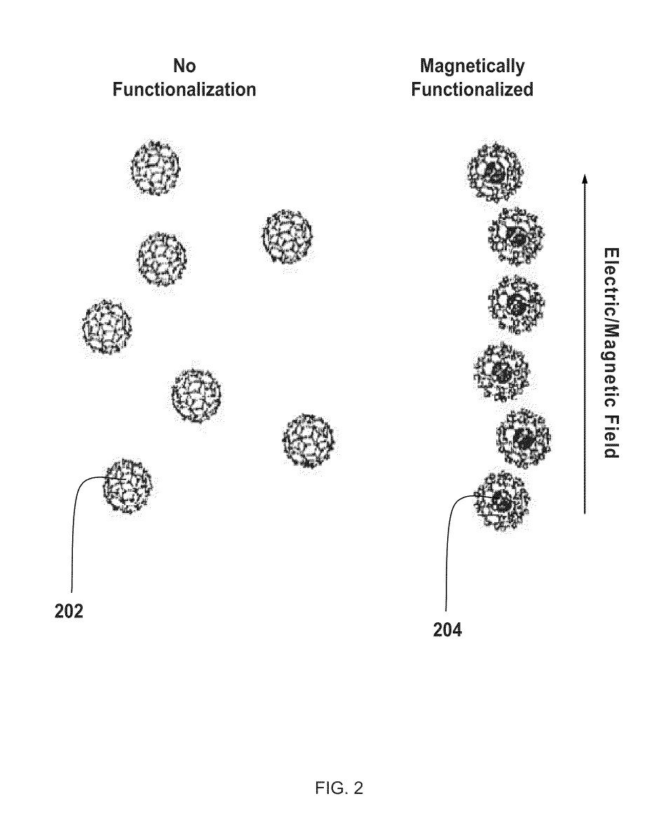

FIG. 2 shows a number of fullerene spherical molecules 202 randomly arrayed as within a matrix. Magnetically functionalized fullerenes 204, in contrast, are aligned along an axis essentially the same as the axis of a force vector of an electromagnetic field. As illustrated, the fullerenes 202, 204 are C₆₀-C₉₆, preferably C₆₀ or C₇₀. When functionalized, they are made in a process that traps inside a metal atom such as iron. Such a process is described, for example in US 2007/0111319, entitled “Synthesis of nanoparticles with a closed structure of metal,” and in US 2007/0048870 to Dong, et al., published Mar. 1, 2007, entitled “Endohedral fullerenes as spin labels and MRI contrast agents.”

Once a magnetic dopant is incorporated into the electron-conducting nanostructure, the molecule will feel a force and respond to an external magnetic or electric field. This effect is shown schematically in FIG. 1 and FIG. 2.

Nanoparticle Material with Magnetic Functionality

The present device employs as an active semiconductor material, preferably as an electron acceptor, particles, which together form electron- or hole- conducting channels, as shown at 104 in FIG. 1. Examples of suitable materials include, but are not limited to, fullerenes such as C₆₀, functionalized C₆₀, such as C₆₀-PCBM, single wall nanotubes; nanotubes such as carbon single walled and multi wall nanotubes, nanowires, and quantum dots.

One class of preferred materials is essentially spherical fullerenes, The term “fullerene” is used generally herein to refer to any closed cage carbon compound containing both six-and five-member carbon rings independent of size and is intended to include the abundant lower molecular weight C₆₀ and C₇₀ fullerenes, larger known fullerenes including C₇₆, C₇₈, C₈₄, C₉₂, C₁₀₆ and higher molecular weight fullerenes C_{2N} where N is 50 or more, including giant fullerenes that can be at least as large as C₄₀₀. The term fullerenes additionally include heterofullerenes in which one or more carbons of the fullerene cage are substituted with a non-carbon element N, etc.) and derivatized/functionalized fullerenes. Toroidal or tetrapodal nanoparticles may also be expected to have mobility in a non-solid matrix and thus are also preferred.

Endohedral fullerenes are fullerene cages that encapsulate an atom or atoms in their interior space. They are written with the general formula Mₘ@C₂ₙ, where M is an element, m is the integer 1, 2, 3, 4, 5, or higher, and n is an integer number. The “@” symbol refers to the endohedral or interior nature of the M atom inside of the fullerene cage. Endohedral fullerenes corresponding to most of the empty fullerene cages have been produced and detected under varied conditions. Endohedral metallofullerenes useful for the present invention, include, but are not limited to those where the element M is a magnetic material much as a metal including iron, some types of steel, manganese, nickel, cobalt and some alloys. Any material, which is attracted to a magnet is “magnetic” for the purpose of this specification.

A range of methods are known in the art for the incorporation of endohedral dopants, including fairly complex chemical reactions that temporarily open one part of the structure and then re-close it after the dopant is incorporated. Examples of methods that may be used include those found in U.S. Pat. No. 5,523,438, titled “Metal-Fullerene intercalation compounds, process for their preparation, and use as catalysts,” issued to Schlogl et al. on Jun. 4, 1996; and “Electronic and magnetic properties of endohedrally doped fullerene Mₙ@C₆₀: A total energy study”, by Li et al., The Journal of Chemical Physics 128, 07304 (2008), both of which are incorporated by reference herein.

As can be seen in FIG. 1C, the methyl ester group which is attached to an alkyl linker group and thence to a C₆₀ fullerene, provides a possible means for chemically linking a metal or other ferromagnetic material to the semiconducting nanoparticle. Both of the illustrated oxygen atoms provide possible linkage to metallic cations.

US 2005/0279399 by Gaudiana et al., published Dec. 22, 2005, entitled “Photoactive materials and related compounds, devices, and methods,” describes fullerene derivatives including a pendant group that may be reacted to prepare a composition including a plurality of covalently bound fullerenes. The pendant group may be a cyclic ether, such as an epoxide. These linking groups may be used to prepare blocks as shown in FIG. 1 and also be used to attach metal atoms to achieve a magnetic responsiveness in the fullerene.

The present nanoparticle materials may be magnetically doped using other methods known in the art, either on their surface, or within the materials. For example, nanotubes may be partially or lightly coated with a magnetic material. This may be accomplished in a variety of ways. In one method, the nanotubes are irradiated with plasma to create defects. The nanotubes are then coated with molecules, such as dendrimers, where the end groups on the molecules are matched to the defects on the nanotube. For example, plasma irradiated nanotubes may first be placed in a hydroxyl solution to reveal —OH groups on the nanotubes, and then put into a solution with magnetic particles. Other methods of surface functionalizing carbon nanotubes may be found in US Patent Application Publication No. 2006/0116433, entitled “Metal coated carbon black, carbon black compositions, and their applications”, by Probst et al; and “Electronic properties of magnetically doped nanotubes”, by Chen and Kawazoe, Bull. Mater. Sci., Vol. 26, No. 1, 2003, pp.105-107, both of which are incorporated by reference herein.

Alternatively, the nanotubes may be rendered magnetic by enclosing a magnetic material within the nanotube. This may be accomplished using methods known in the art. In one example, the magnetic material is enclosed according to U.S. Pat. No. 5,457,343, entitled “Carbon nanotube enclosing a foreign material”, issued to Ajayan et al. on Oct. 10, 1995.

In the present method, elongated structures are preferred over more spheroid particles, in that the latter are more difficult to arrange into an elongated structure, which will conduct to an electrode. Thus it is preferred to use elongated structures such as nanotubes. In particular, one may use nanotubes filled with, or embedded with magnetic nanoparticles. Preparation of such materials may be accomplished as described in D. Mattia, C. Korneva, A. Sabur, G. Friedman, Y. Gogotsi, “Multifunctional carbon nanotubes with nanoparticles embedded in their walls,” Nanotechnology 18, 155305 (2007). The amount of metal particles to be used will be chosen according to the desired bandgap in the nanotube. The particles should not be present in amounts that will eliminate the semiconductor properties of the nanotube. The bandgap of a SWNT (single walled nanotube) strongly depends on its diameter and chirality (chemical “handedness”) (M. S. Dresselhaus, G. Dresselhaus, P. Avouris, Eds., “Carbon Nanotubes: Synthesis, Structure, Properties, and Applications,” vol. 80 (Springer, Berlin, 2001). The bandgap of semi-conducting SWNTs is roughly inversely proportional to its diameter, i.e., Eg (in eV)≈1/d (diameter in nm) for semi-conducting SWNTs. The bandgap has a dependence of Eg (in eV)≈1/d² (diameter in nm) for the semi-metallic SWNTs [R. Saito. G. Dresselhaus, and M. S. Dresselhaus, Physical Properties of Carbon Nanotubes, Imperial College Press, London, 1998;]. This means the SWNTs cover a wide range of the spectrum of optical absorption from infrared to far-infrared. Furthermore, with the development of carbon nanotube synthesis technology, it is possible to control the bandgap SWNTs in a certain range.

Quantum dots are semiconductor nanoparticles that exhibit size and compositionally tunable bandgaps. Therefore, different types and sizes of quantum dots, engineered to perfectly match and absorb the light of the solar spectrum, can be brought together into the same cell. High-quality, defect-free, self-assembled quantum dots can be obtained during the early stage of growth of highly strained semiconductors (see for example: S. Fafard, et al., “Manipulating the Energy Levels of Semiconductor Quantum Dots”, Phys. Rev. B 59, 15368 (1999) and S. Fafard, et al., “Lasing in Quantum Dot Ensembles with Sharp Adjustable Electronic Shells,” Appl. Phys. Lett. 75, 986 (1999)). Such quantum dot material can be grown in multiple layers to achieve thick active regions. The interband absorption properties of the quantum dot material can be tailored to cover various wavelength ranges in the near infrared and visible portions of the optical spectrum. The composition, size and shape of the quantum dot material are adapted to change the quantization energies and the effective bandgap of the quantum dot material, where the effective bandgap of the material is defined as essentially being the lowest energy transitions at which photons can be absorbed and is determined by the quantized energy levels of the heterostructure.

Other nanocrystals can be used, such as a quantum dot composed of ZnSe, ZnSe/ZnS, ZnSe/ZnSeS, ZnS, or ZnTe. In another preferable embodiment, the nanocrystal of the present invention comprises a core containing ZnSe, ZnTe, or ZnS, a first shell containing CdSe, and a second shell containing PbSe. The quantum dots may be magnetically functionalized by doping with ferromagnetic atoms, or arranging the quantum dot, e.g., as described in Shiraishi et al., “Design of a semiconductor ferromagnet in a quantum-dot artificial crystal,” Appl. Phys. Lett. 78, 3702 (2001).

Thus one embodiment of the present invention employs magnetic quantum dots in a polymeric matrix. Such magnetic quantum dots may be prepared as described in Schwartz et al., “Magnetic Quantum Dots: Synthesis, Spectroscopy, and Magnetism of Co2+- and Ni2+-Doped ZnO Nanocrystals,” J. Am. Chem. Soc., 125 (43), 13205 -13218, 2003. There, Co²⁺ and Ni²⁺ dopants inhibited nucleation and growth of ZnO nanocrystals, but were included during growth.

### Polymer Matrix Material

The material in the present device that absorbs light and in response generates an exciton (i.e., a bound electron/hole pair) is refereed to as the matrix material (102 in FIG. 1). It is typically an organic polymer. The photovoltaic material is preferably a polymer such as P3HT, PEDOT, MDMO-PV, or PFTBT. Also preferably, the polymer is hole-conducting, such that electrons and holes are spatially separated in the device. Examples of suitable polymers, as well as methods of making such polymers can be found, e.g., in “Polymer based photovoltaics: Novel concepts, materials, and state-of-the art efficiencies”, by Kroon et al, published in the proceedings of the European Photovoltaic Solar Energy Conference and Exhibition, 2005.

Poly (e-hexylthiophene), P3HT, is useful in that incident light is absorbed mainly over the wavelength range of 450 nm to 600 nm. Another organic material that may be employed is 3,4,9,10-perylenetetracarboxylic-bis-benzimidazole (PTCBI). The actual thickness of the organic polymer absorber must generally be very thin, on the order of about 100 to 150 nm. One may also use polymers based on copper iodine chains. By using a co-crystal scaffolding, poly(diiododiacetylene), or PIDA, can be prepared as a nearly unadorned carbon chain substituted with only single-atom iodine side groups. The monomer, diiodobutadiyne, forms co-crystals with bis(nitrile) oxalamides, aligned by hydrogen bonds between oxalamide groups and weak Lewis acid-base interactions between nitrites and iodoalkynes. In co-crystals with one oxalamide host, the diyne undergoes spontaneous topochemical polymerization to form PIDA. Further details are set forth in Sun et al., “Preparation of poly(diiododiacetylene), an ordered conjugated polymer of carbon and iodine,” Science, 2006 May 19; 312(5776):1030-4.

Other suitable polymeric materials include N,N′-di(naphthalen)-N,N′-diphenyl-benzidine(NPB), N,N′-bis(naphthalen-1-yl)-N,N′-bis(phenyl)benzidine(α-NPB), N,N′-di(naphthalene-1-yl)-N,N′-diphenyl-9,9,-dimethyl-fluorene(DMFL-NPB), N,N′-di(naphthalene-1-yl)-N,N′-diphenyl-spiro(Spiro-NPB), N,N′-Bis-(3-methylphenyl)-N,N′-bis-(phenyl)-benzidine (TPD), N,N′-bis-(3-methylphenyl)-N,N′-bis-(phenyl)-spiro (Spiro-TPD), N,N′-bis-(3-methylphenyl)-N,N′-bis-(phenyl)-9,9-diphenyl-fluorene(DMFL-TPD), 1,3-bis(carbazol-9-yl)-benzene(MCP), 1,3,5-tris(carbazol-9-yl)-benzene(TCP), N,N,N′,N′-tetrakis(naphth-1-yl)-benzidine(TNB), poly(N-vinyl carbazole)(PVK), poly(2-methoxy-5-(2-ethylhexyloxy)-1,4-phenylenevinylene)(MEH-PPV), poly[2-Methoxy-5-(2′-ethylhexyloxy)-1,4-phenylenevinylene-co-4,4′-bisphen-ylenevinylene](MEH-BP-PPV), poly[(9,9-dioctylfluoren-2,7-diyl)-co-(1,4-diphenylene-vinylene-2-methoxy--5-{2-ethylhexyloxy}benzene)](PF-BV-ME), poly[(9,9-dioctylfluoren-2,7-diyl)-co-(2,5-dimethoxy benzen-1,4-diyl)](PF-DMOP), poly[(9,9-dihexylfluoren-2,7-diyl)-alt-co-(benzen-1,4-diyl)](PFH), poly[(9,9-dihexylfluoren-2,7-diyl)-co-(9-ethylcarbazol-2,7-diyl)](PFH-EC)- , poly[(9,9-dihexylfluoren-2,7-diyl)-alt-co-(2-methoxy-5-{2-ethylhexyloxy}-phenylen-1,4-diyl)](PFH-MEH), poly[(9,9-dioctylfluoren-2,7-diyl)(PFO), poly[(9,9-di-n-octylfluoren-2,7-diyl)-co-(1,4-vinylenephenylene)](PF-PPV)- , poly[(9,9-dihexylfluoren-2,7-diyl)-alt-co-(benzen-1,4-diyl)](PF-PH), poly[(9,9-dihexylfluoren-2,7-diyl)-alt-co-(9,9′-spirobifluoren-2,7-diyl)](PF-SP), poly(N,N′-bis(4-butylphenyl)-N,N′-bis(phenyl)benzidine(poly-TPD), poly(N,N′-bis(4-butylphenyl)-N,N′-bis(phenyl) benzidine(poly-TPD-POSS), poly[(9,9-dihexylfluoren-2,7-diyl)-co-(N,N′-di(4-butylphenyl)-N,N′-diphen-yl-4,4′-diyl-1,4-diamino benzene)](TAB-PFH), N,N′-pis(phenanthren-9-yl)-N,N′-diphenylbenzidine(PPB), tris-(8-hydroxy quinoline)-aluminum(Alq3), bis-(2-methyl-8-quinolinolate)-4-(phenylphenolato)-aluminium(BAlq3), 2,9-dimethyl-4,7-diphenyl-1,10-phenanthroline(BCP), 4,4′-bis(carbazol-9-yl) biphenyl(CBP), 3-(4-Biphenylyl)-4-phenyl-5-tert-butylphenyl-1,2,4-triazole(TAZ), MEH-PPV, MEH-BP-PPV, PF, PF-BV-MEH, PF-DMOP, PFH-EC, PFH-MEH, PFO, PFOB, PF-PPV, PF-PH, PF-SP, poly-TPD, poly-TPD-POSS, TAB-PFH, PPB, or a combination thereof.

Components in photovoltaic cell other than the electron acceptor materials and the electron donor materials are known in the art.

In some embodiments, the polymer described above can be used as an electron donor material or an electro acceptor material in a system in which two photovoltaic cells share a common electrode. Such a system is also known as tandem photovoltaic cell.

Selecting Combinations of Polymer Matrix Material and Nanoparticle with Magnetic Functionality

The polymers described above can be useful in solar power technology because the band gap is suitable for a photovoltaic cell (e.g., a polymer-fullerene cell). The effectiveness of an excitonic photovoltaic cell depends in part on matching the band gap between the electron donor and acceptor. The band gap is the energy difference between the highest energy level filled with electrons and the lowest energy level that is empty. In an inorganic semiconductor or inorganic insulator, this energy difference is the difference between the valence band edge EV (top of the valence band) and the conduction band edge EC (bottom of the conduction band). The band gap of a pure material is devoid of energy states where electrons and holes can exist. The only available carriers for conduction are the electrons and holes, which have enough energy to be excited across the band gap. In general, semiconductors have a relatively small band gap in comparison to insulators.

To control the band gap, the HOMO (highest occupied molecular level) level of the polymers can be positioned correctly relative to the LUMO (lowest unoccupied molecular level) of an electron acceptor (e.g., PCBM) in a photovoltaic cell (e.g., a polymer-fullerene allowing for high cell voltage. The LUMO of the polymers used here can be positioned correctly relative to the conduction band of the electron acceptor in a photovoltaic cell, thereby creating efficient transfer of an electron to the electron acceptor.

In terms of an energy band model, excitation of a valence band electron into the conduction band creates carriers; that is, electrons are charge carriers when on the conduction-band-side of the band gap, and holes are charge carriers when on the valence-band-side of the band gap.

A first energy level is “above”, a second energy level relative to the positions of the levels on an energy band diagram under equilibrium conditions, As is the convention with inorganic materials, the energy alignment of adjacent doped materials is adjusted to align the Fermi levels (E_{F}) of the respective materials, bending the vacuum level between doped-doped interfaces and doped-intrinsic interfaces. As noted previously, the magnetic functionality is also considered in the design of the band gap, but is not expected to have a significant effect.

In addition, carrier mobility is a significant property in inorganic and organic semiconductors. Mobility measures the ease with which a charge carrier can move through a conducting material in response to an electric field. In comparison to semiconductors, insulators generally provide poor carrier mobility.

The present devices employ materials, which are matched according to these known principles.

For example, using a polymer having a band gap of about 1.4-1.6 eV can significantly enhance cell voltage. Cell performance, specifically efficiency, cam benefit from both an increase in photocurrent and an increase in cell voltage, and can approach and even exceed 15% efficiency. The positive charge mobility of the polymers can be relatively high and. approximately in the range of 10-4 to 10-1 cm2/Vs. general, the relatively high positive charge mobility allows for relatively fast charge separation. The polymers can also be soluble in an organic solvent and/or film forming. Further, the polymers can be optically non-scattering.

A further listing of donor and acceptor materials useful in the present invention is found Kietzke, “Advances in Organic Solar Cells,” Advances in OptoElectronics, Volume 2007, Article ID 40285, published on line, which presents the following table, where η is efficiency, V_{OC} is open circuit voltage, FF is fill factor and IPCE is incident photon to current efficiency.

TABLE 1

| Donor | Acceptor | η | V_{OC} | FF | IPCE |
|---|---|---|---|---|---|
| CuPc | C60 | 5.7% | 1.0 V | 59% | NA |
| CuPc | C60 | 5.0% | 0.6 V | 60% | 64% |
| MeO-TPD, ZnPc (stacked) | C60 | 3.8% | 1.0 V | 47% | NA |
| CuPc | C60 | 3.5% | 0.5 V | 46% | NA |
| DCVST | C60 | 3.4% | 1.0 V | 49% | 52% |
| CuPc | PTCBI | 2.7% | 0.5 V | 58% | NA |
| SubPc | C60 | 2.1% | 1.0 V | 57% | NA |
| MeO-TPD, ZnPc | C60 | 2.1% | 0.5 V | 37% | NA |
| TDCV-TPA | C60 | 1.9% | 1.2 V | 28% | NA |
| Pentacene on PET | C60 | 1.6% | 0.3 V | 48% | 30% |
| SnPc | C60 | 1.0% | 0.4 V | 50% | 21% |

Dasd In an alternative embodiment, the present method may be used to attach magnetic atoms to particles, which are coupled to dyes and arranged in a polymeric matrix. Such a device is known as a dye sensitized solar cell, and is described for example in U.S. Pat. No. 6,756,537 to Kang, et al., issued Jun. 29, 2004, entitled “Dye-sensitized solar cells including polymer electrolyte gel containing poly(vinylidene fluoride).” See also, US 20030152827 by Ikeda, et al., published Aug. 14, 2003, entitled “Dye-sensitized photoelectric transducer,” In an exemplary embodiment, TiO2 particles coated with dye molecules and dispersed in an electrolyte are magnetically arranged by making the TiO2 particles magnetically responsive, e.g., by doping with Co, Fe or the like.

### Electromagnetic Field

The photovoltaic material must be in a form at the time that the electromagnetic field is applied which allows the nanoparticles to align along the field lines. Typically, this will be a polymer in monomeric or prepolymer form in a solvent or dispersant. The electron-conducting material may be blended into the polymer and subjected to a static and/or ac field by means of current coils or capacitor plates, or by applying an electrical current through the mixture. Alternatively, a magnetic field may be established by a permanent magnet or an electromagnet. For materials that are weakly magnetically responsive, fields on the order of 1 to 0 tesla may be used. For ferromagnetic materials, only a few gauss will be necessary in most cases. Similarly, electric fields on the order of a few Wm may be used, whereas poorly responsive materials may be subjected to MV/cm.

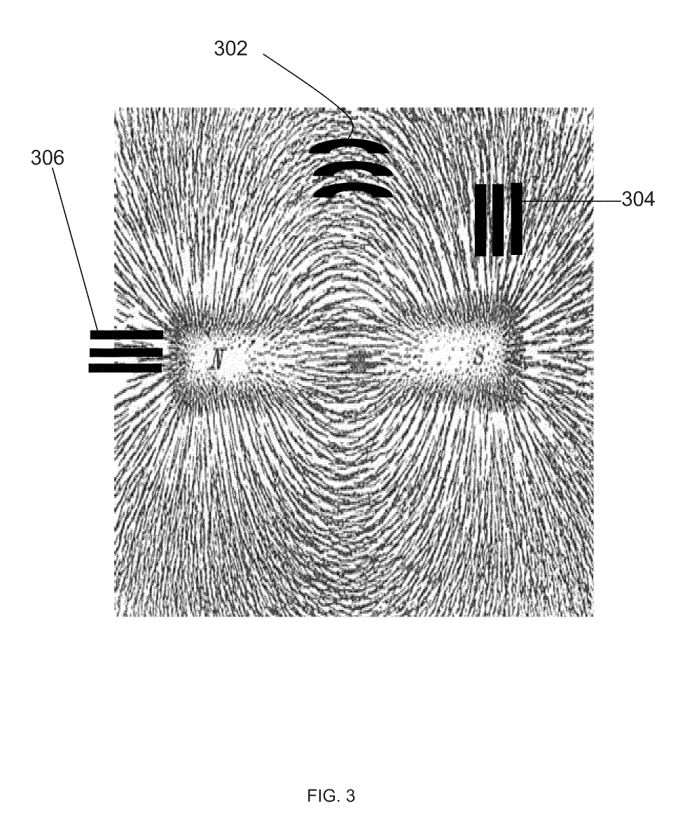

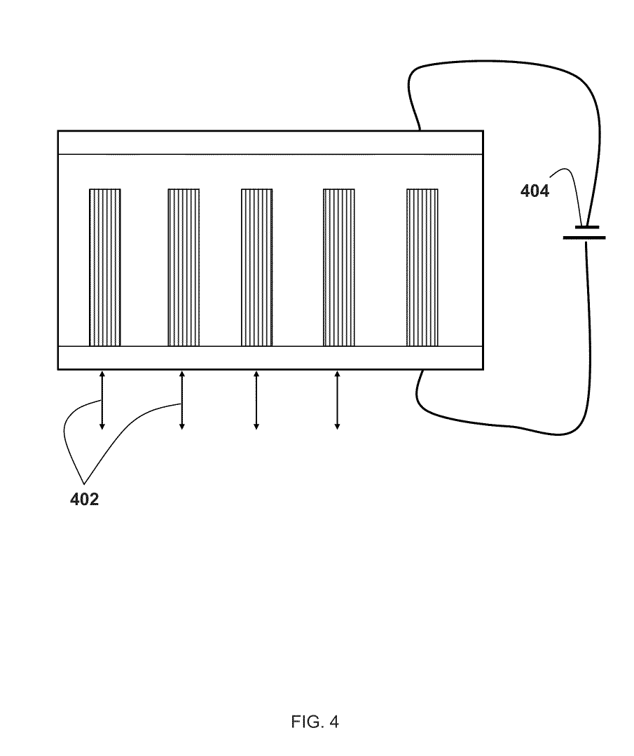

Applying the magnetic or electric field may be accomplished by means known in the art. Referring now to FIG. 3, it can be seen that alignment of nanoparticles will result of exposure to a simple bar magnet having North and South poles. At 302, it can be seen that the present configuration need not be linear, but may be arcuate. Parallel linear alignments of particles along force field lines may be directed as shown at 304 and 306 near either pole, parallel or orthogonal to the length of the magnet. The electromagnetic force may be applied in the present method in a variety of configurations, and can be employed so as to “stack” spherical particles as shown in FIG. 2 and FIG. 4.

In addition, as shown in FIG. 4, small, spaced individual magnets 402 may be used to create distinct columns in a parallel army. Also, as shown at 404, an electrical source may be connected across the photovoltaic polymer to create an electric field which will cause alignment of the nanoparticles in a similar manner, it being understood that the voltage plates or magnets will be machined to a very small scale, on the order of 10-20 nm apart. The electrical source may be DC or AC, e.g., 1-10,000 V/m and may be of a high frequency, e.g., 20 kHz.

The present electromagnetic field may also be applied in conjunction with presently used methods of aligning particles, such as centrifugation, which is used with spherical fullerene particles.

### Processing

The polymeric photoactive layer may contain a wide range of particle concentrations, typically about 20 wt % to 85 wt % of nanoparticles, which are first formed by methods described above, and then functionalized with a magnetic group, unless the nanoparticle is sufficiently intrinsically magnetically responsive. The particles are then added to a polymer in a fluid form, which is then applied to a substrate, e.g., by spin coating a thin layer (e.g., 60-300 nm) on to the substrate. The functionalized nanocomposite photoactive matrix might be provided as a hopper or liquid tank that is fluidly coupled to a deposition system for providing a photoactive layer on a substrate. Such deposition systems might include spraying nozzles, printing heads, screen printing apparatuses, spreading blades, i.e., doctor blades, sheer coating systems, or other useful systems for depositing even, thin films of material, including, e.g., dispensing systems over spin coaters, tape casting systems, film casting systems, and dip coating systems. While the mixture is not in a completely rigid state, the described electromagnetic field is applied to orient the nanoparticles. The electromagnetic field is applied to the composite of polymeric (or prepolymeric on monomeric) matrix. The electromagnetic field produces force lines as shown in FIG. 3 and aligns and orients the nanoparticles. The nanoparticles are arranged and blended to be in intimate contact with the polymer matrix, and spaced apart so that they are in close proximity, approximating the electron hole recombination length, i.e. less than about 200 nm, or less than 100 nm, or less than 80 nm, or less than 10 nm. It is contemplated that the polymer will be in a thin film on a substrate, and may have an upper electrode or coating as well. The electromagnetic apparatus thus does not directly touch the nanoparticles or the matrix. The field is applied across the thin film. Then, heating, drying and/or curing steps are employed to complete the photovoltaic layer by hardening (curing) the polymer. Blocking layers, electrodes and the like are then applied, as is known in the field of photoelectronics, to achieve a working photovoltaic cell. It is also contemplated that multilayer cells can be prepared; these can be exposed to the electromagnetic force as separate layers, or as a sandwich. Multiple layers, using transparent electrodes, are advantageous in that incoming light may pass through multiple layers, each tuned to a different portion of the solar spectrum, in order to extract more solar energy.

It should also be noted that one can adjust or tune the absorption spectrum of the active layer or layers by adjusting the composition of the nanostructure (e.g., nanocrystal) component or, components to fit the needs of the particular application. In particular, the absorption spectrum of semiconductor nanocrystals can be adjusted depending upon the composition and/or size of the nanocrystals. For example, InAs nanorods have a greater absorption in the near IR range, e.g., the absorption is red shifted as compared to other nanorods, InP nanorods have a greater absorption in the visible range, CdSe rods have greater absorption in the visible to blue range, while CdS nanorods have an absorption spectrum that is further blue shifted than CdSe nanorods. Utilizing transparent electrodes, the present devices may be formed as sandwiches of differently tuned photovoltaics.

### CONCLUSION

The methods and materials described herein allow for a completely new way to control the nanoscale morphology of the new classes of blended photovoltaic devices, which may tie at the heart of substantially improved efficiencies. The present techniques, given the above disclosure, may also be applied to a number of devices and applications, including, but not limited to, various photovoltaic devices, optoelectronic devices (LEDs, nanolasers), light collectors, and the like.

The above specific description is meant to exemplify and illustrate the invention and should not be seen as limiting the scope of the invention, which is defined by the literal and equivalent scope of the appended claims. Any patents or publications mentioned in this specification are indicative of levels of those skilled in the art to which the patent or publication pertains as of its date and are intended to convey details of the invention which may not be explicitly set out but which would be understood by workers in the tied. Such patents or publications are hereby incorporated by reference to the same extent as if each was specifically and individually incorporated by reference, such incorporation being for the purpose of further describing and enabling the method or material referred to.

What is claimed is:

1. A photovoltaic device comprising a polymer material and a nanoparticle material within the polymer material,
one of said materials forming an electron donor and another of said materials forming electron acceptor material,
wherein the nanoparticle material includes a magnetic functionality and is arranged within the polymer material along lines as produced by an electromagnetic field.

2. The device of claim 1 wherein the polymer material comprises the electron donor and a magnetically modified fullerene comprises the electron acceptor material.

3. The device of claim 1 wherein the nanoparticle material comprises the electron donor and is selected from the group consisting of C₆₀, functionalized C₆₀, a single wall nanotube, a multiwall nanotube, a nanowire, and a quantum dot.

4. The device of claim 3 wherein the functionalized C₆₀ comprises C₆₀-PCBM ([6,6]-phenyl-C61-butyric acid methyl ester).

5. The device of claim 1 wherein the polymer material comprises P3HT.

6. The device of claim 1 wherein the polymer material is selected from the group consisting of P3HT (Poly(3-Hexylthiophene), PEDOT (Poly(3,4-ethylenedioxythiophene)), MDMO-PV (poly(2-methoxy-5-(3′,7′-dimethyl-octyloxy))-p-phenylene vinylene), polyacetylene (PA), polyparaphenylenevinylene (PPV), P3OT (poly (3-octylthiophene) and PFTBT (poly fluorene-benzothiadiazole) and mixtures thereof.

7. The device of claim 1 wherein the polymer material comprises a hole-conducting polymer.

8. The device of claim 1, 6 or 7 wherein the magnetic functionality is provided by a material selected from the group consisting of manganese, chromium, iron, cobalt and nickel.

9. The device of claim 1 wherein the lines define nanostructured electron-conducting channels having a channel-to-channel spacing no larger than an electron-hole recombination length in photovoltaic material.

10. The device of claim 1 wherein said device comprises a solar cell device having multiple photovoltaic layers.

11. A method of making a photovoltaic device comprising the steps of:
(a) preparing a mixture of a polymer material and a magnetically responsive nanoparticle material within the polymer material, wherein one of said materials comprises electron donor material and the other of said materials comprises electron acceptor material;
(b) applying the mixture as a thin film to a substrate;
(c) applying an electromagnetic field to the mixture across the thin film to align nanoparticie material along lines of an electromagnetic field, thereby resulting in polymeric material; and
(d) curing the polymeric material to fix the nanoparticle material in alignment.

12. The method of claim 11 further comprising the step of doping the nanoparticle with a ferromagnetic.

13. The method of claim 12 wherein said doping comprises endohedral doping.

14. The method of claim 11 further comprising the step of applying an electric current to the mixture while applying the electromagnetic field to the mixture.

15. The method of claim 11 further comprising the step of applying metal electrodes to the polymer material, wherein one electrode contacts the nanoparticle material.

16. The method of claim 11 wherein the nanoparticle material and the polymer material are present in less than a 1:1 ratio of particles to polymer.

17. The method of claim 11 wherein the thin film is 100-300 nm thick.

18. The method of claim 11 wherein the nanoparticle material comprises a fullerene which contains a metal atom.

19. The device of claim 3 wherein the functionalized C₆₀ comprises C₆₀-fused pyrrolidine-meta-C₁₂ phenyl (C60MC12).

20. The device of claim 1 wherein the polymer material comprises PEDOT.

21. The device of claim 4 wherein the polymer material comprises P3HT.

22. The device of claim 4 wherein the polymer material comprises PEDOT.

23. The device of claim 6 wherein the magnetic functionality is provided by a material selected from the group consisting of manganese, chromium, iron, cobalt and nickel.

24. The device of claim 7 wherein the magnetic functionality is provided by a material selected from the group consisting of manganese, chromium, iron, cobalt and nickel.

25. The method of claim 11 further comprising the step of doping the nanoparticle with a paramagnetic material.

26. The method of claim 12 wherein said doping comprises surface functionalization.

27. The method of claim 12 further comprising the step of applying an electric current to the mixture while applying the electromagnetic field to the mixture.
